(19) United States
(12) Patent Application Publication
(10) Pub. No.: US 2020/0333713 A1
(43) Pub. Date: Oct. 22, 2020

(54) SEPARATED AXIS LITHOGRAPHIC TOOL

(71) Applicant: Onto Innovation, Inc., Wilmington, MA (US)

(72) Inventor: J. Casey DONAHER, Westford, MA (US)

(73) Assignee: Onto Innovation, Inc, Wilmington, MA (US)

(21) Appl. No.: 16/955,808

(22) PCT Filed: Dec. 26, 2018
(86) PCT No.: PCT/US2018/067467

§ 371 Date: Jun. 19, 2020

Related U.S. Application Data
(60) Provisional application No. 62/611,210, filed on Dec. 28, 2017.

(51) Int. Cl. G03F 7/20

(52) U.S. Cl. CPC G03F 7/70425; G03F 7/707

(57) ABSTRACT

A stepper (100) for lithographic processing of semiconductor substrates includes abase (102), a chuck (104) that moves only along an X axis of a coordinate system, a bridge (114) mounted over the base and the chuck, and at least one projection camera (112) mounted on the bridge. The at least one projection camera is movable along a Y axis of the coordinate system. The combined range of travel of the chuck along the X axis and the at least one projection camera along the Y axis is sufficient to address a field of view of the at least one projection camera to substantially an entire substrate (106) mounted on the chuck.

### CROSS-REFERENCE TO RELATED APPLICATIONS

This application claims the benefit of U.S. Provisional Application No. 62/611,210, filed Dec. 28, 2017, the disclosure of which is incorporated herein by reference in its entirety.

### INTRODUCTION

In semiconductor lithography (also called photolithography or, simply, lithography) patterns are created on silicon wafers using a light sensitive polymer called a photoresist. Optical lithography is basically a photographic process by which the photoresist is exposed and developed to form three-dimensional relief images on the substrate. Etching step is then performed that removes either the exposed or the un-exposed photoresist, uncovering the substrate below the removed photoresist. This exposed substrate is then etched to obtain the three-dimensional surface.

In general, the ideal photoresist image has the exact shape of the designed or intended pattern in the plane of the substrate, with vertical walls through the thickness of the resist. Thus, the final resist pattern is binary: parts of the substrate are covered with resist while other parts are completely uncovered. This binary pattern is needed for pattern transfer since the parts of the substrate covered with resist will be protected from etching, ion implantation, or other pattern transfer mechanism.

There are two major classes of projection lithography tools—scanning and step-and-repeat systems. Scanning projection printing employs reflective optics (i.e., mirrors rather than lenses) to project a slit of light from the mask onto the substrate wafer as the mask and wafer are moved simultaneously by the slit. Step-and-repeat cameras (called steppers for short) expose the wafer one rectangular section (called the image field) at a time and then the wafer is moved stepwise to the next position and the fixed camera is triggered again. By moving only the substrate relative to a fixed camera, complexity is reduced and the fine control necessary for proper quality assurance is easier to achieve.

To build the complex structures that make up a transistor and the many wires that connect the millions of transistors of a circuit, lithography and etch pattern transfer steps are repeated many times to make one circuit. Each pattern being printed on the wafer is aligned to the previously formed patterns and slowly the conductors, insulators, and selectively doped regions are built up to form the final device.

Lithographic tools with bases having moveable chucks carrying substrates that are moved relative to fixed cameras are known in the art. Various designs are known but a common design is a two camera system described in U.S. Pat. No. 7,385,671 to Gardner, et al., the disclosure of which is hereby incorporated by reference. In some designs, the chuck is supported above the base on a cushion of air created by air bearings and is moved in the XY plane defined by the surface of the base by a planar or Sawyer motor (the components of which are omitted for clarity's sake). The chuck can be moved in the two dimensions over the base in a range sufficient to address an entire substrate to a pair of cameras or other process tools. Ideally, it would be easy to form a perfectly planar base and chuck such that a substrate S would be translated relative to fixed projection cameras in an XY plane perpendicular to an optical axis of the projection cameras. As a projection camera has a depth of field of limited dimension along the optical axis, it is important that the substrate be maintained within this limited range.

### DESCRIPTION OF THE FIGURES

FIG. 1A is a perspective view of an embodiment of a lithography system.

FIG. 1B is a schematic cross section of an embodiment of a lithography system taken along section lines Y-Y in FIG. 1A.

FIG. 1C is a schematic cross section of an embodiment of a lithography system taken along section lines X-X in FIG. 1A.

FIG. 1D is a schematic top view of the base and stage of an embodiment of a lithography system showing an aspect of the positioning of projection cameras relative to a substrate.

FIG. 1E is a schematic top view of the base and stage of an embodiment of a lithography system showing an aspect of the positioning of projection cameras relative to a substrate.

FIG. 2A is a schematic cross sectional representation of a single projection camera addressed to a substrate.

FIG. 2B is a schematic top view of the base and stage of an embodiment of a lithography system showing an aspect of the positioning of a projection camera relative to a substrate.

FIG. 2C is a schematic top view of the base and stage of an embodiment of a lithography system showing an aspect of the positioning of a projection camera relative to a substrate.

### DETAILED DESCRIPTION

Before the separated axis lithographic tools and systems are disclosed and described, it is to be understood that this disclosure is not limited to the particular structures, process steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting. It must be noted that, as used in this specification, the singular forms “a,” “an,” and “the” include plural referents unless the context clearly dictates otherwise.

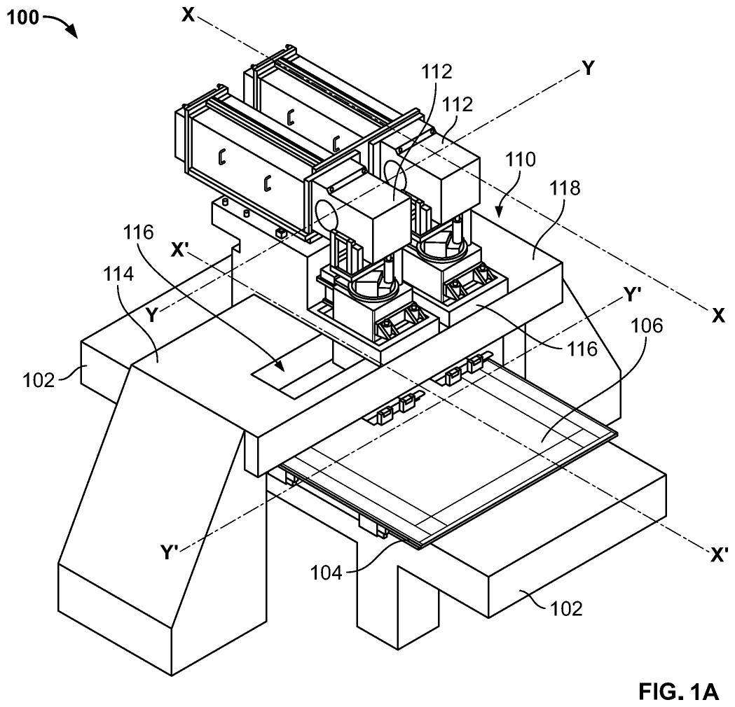

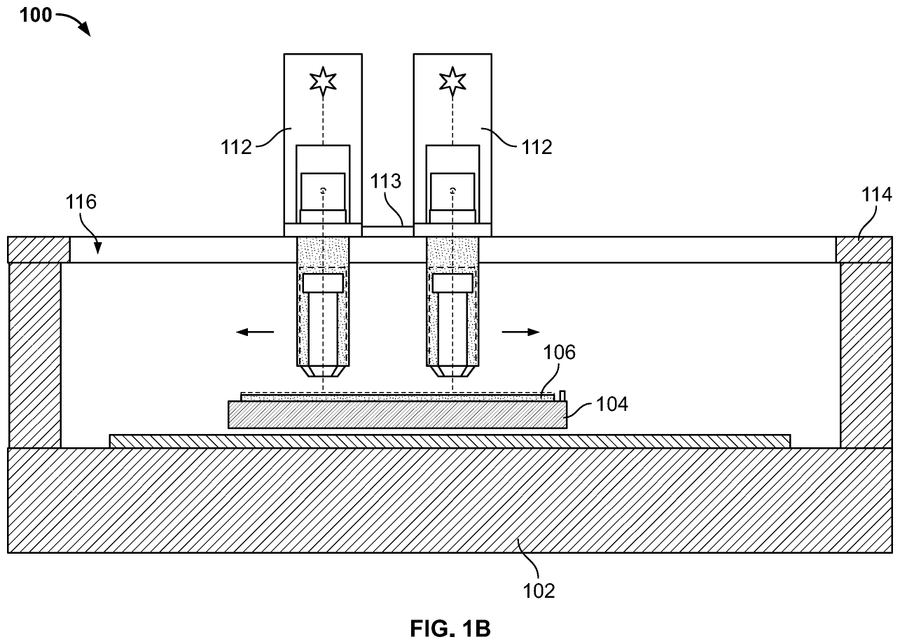

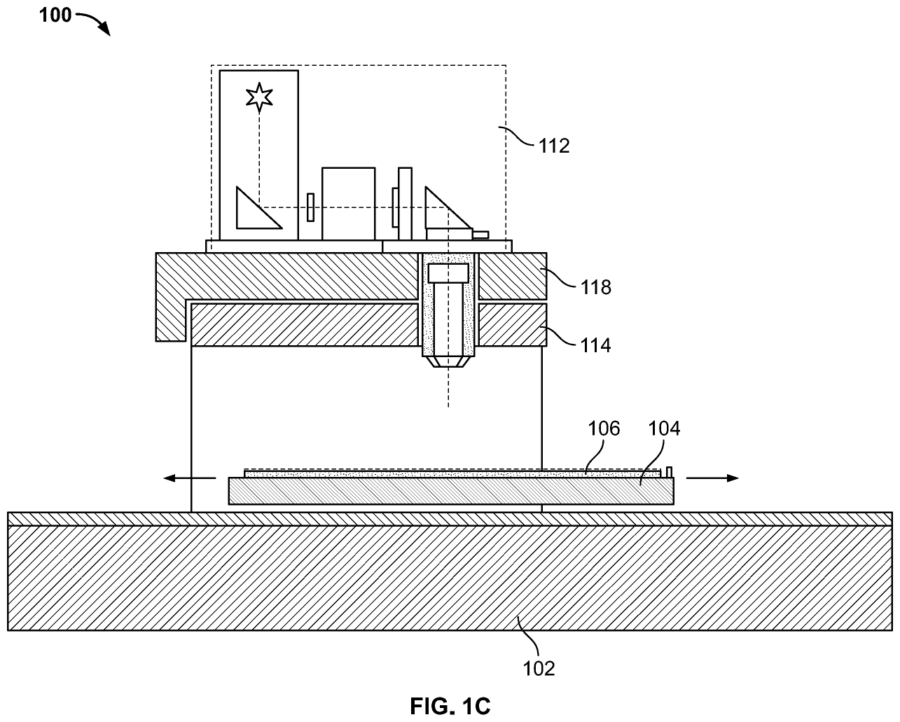

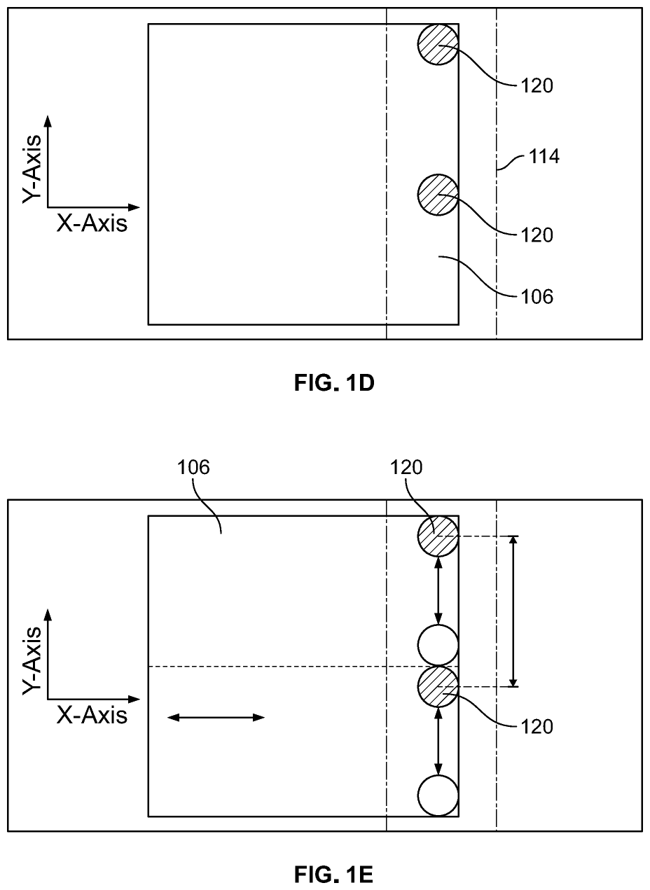

FIGS. 1A-1E illustrate different views of an embodiment of a separated axis lithographic tool. The term ‘separated axis’ is used to describe lithography devices in which the substrate and the camera both move and move along different axes. The substrate will be referred to as moving along the X axis and the camera(s) will be referred to as moving along the Y axis. In the embodiment shown in FIGS. 1A-1E, the X and Y axes are perpendicular to each other, however this is just one embodiment of a separated axis lithographic tool and any non-parallel pair of axes may be used. The X and Y axes are illustrated in FIG. 1A with section lines that also define the cross-sections for the views shown in FIGS. 1B and 1C.

FIG. 1A illustrates a perspective view of an embodiment of a separated axis lithographic tool. In the embodiment shown, the lithographic tool 100 includes a base 102 on which a chuck 104 moves horizontally in a single direction, in this case the X direction. The base 102 and chuck 104 together are sometimes referred to a stage. The chuck 104 is a large platform that carries and supports the substrate 106. The chuck 104 has a sufficient range of movement in the X direction to allow the entire length (i.e., dimension of the substrate along the X axis) of the substrate to be passed under the camera assembly 110 and imaged (addressed) by the camera(s) 112. Additional range of motion may be provided to assist in the receiving and removal of the substrate. In some embodiments, the chuck 104 is constrained to move only in the X direction. That being said, some adjustment in the Y direction or in the XY plane may be permitted for adjustment of the attitude of the chuck 104 as it moves relative to the projection camera 112 of the tool 100.

In the embodiment shown, the camera assembly 110 includes two cameras 112 suspended over the base 102/chuck 104/substrate 106 by a bridge 114. The two cameras 112 are attached to a moveable sled 118 that can move across the surface of the bridge 114. In an embodiment the sled 118, similar to the chuck 104, moves on a cushion of air created by air bearings and is moved along the Y axis by a planar or Sawyer motor. Other mechanisms for moving the cameras 112 and sled 118 known and any suitable technology for moving the cameras 112 and sled 118 now known or later developed may be used.

The bridge 114 is positioned over the base 102 and the chuck 104 that moves thereover and is provided with a Y-axis slot 116 through which the cameras 112 translate. In the embodiment shown, the two cameras are separated by a fixed distance, the distance between the cameras referred in the art as the ‘pitch’. In order to maintain the necessary tolerances when imaging the photoresist on the substrate, the pitch must be known and controlled to an acceptable degree. Note that in all instances, focusing and/or alignment mechanisms of types well known to those skilled in the art are employed in conjunction with each camera assembly to reduce or remove lower and higher order optical aberrations such as defocus, tilt, rotation, and the like. Such focusing and alignment mechanisms are omitted from this description for the sake of clarity.

In an alternative embodiment, the pitch may be variable and may be controlled mechanically or otherwise. A pitch adjustment mechanism 113 (FIG. 1B) for this purpose is coupled between the first and second projection cameras. The pitch adjustment mechanism 113 may include a fine stepper motor system having a plurality of positions, in which each position corresponds to a different pitch between the first and second projection cameras. The pitch adjustment mechanism 113 may then be automatically and continuously adjustable by actuating the stepper motor to shorten or lengthen the distance between the respective cameras 112. In one embodiment, the pitch adjustment mechanism 113 includes a screw mechanism (not shown) that is actuated by the stepper motor. In another embodiment, the pitch adjustment mechanism 113 may include only a screw mechanism without a stepper motor or any other type of automatic actuator. In embodiments of this type the pitch between the respective cameras 112 is set and remains static during use.

FIG. 1B illustrates a cross-sectional view of the lithographic tool along the Y axis through the slot of the camera bridge. The two cameras 112 are illustrated suspended above the substrate 106 and are able to move laterally as shown by the arrows. Again, in this embodiment the two cameras have a fixed pitch so that they move together. The cameras are provided sufficient range of movement in the Y direction so that the combined range of travel of chuck 104 along the X axis and the cameras 112 along the Y axis is sufficient to address a field of view of cameras 112 to substantially all of the substrate, as shown in FIG. 1E.

FIG. 1C illustrates a cross-sectional view of the lithographic tool along the X axis through one of the two cameras. Detail of the design of the bridge 114 and camera 112 system can be seen. In the embodiment shown, the cameras 112 are on a movable sled 118 that rides along a fixed bridge portion 114.

FIGS. 1D and 1E schematically illustrate a top down view showing the motion of the cameras 112 in the Y axis relative to a substrate 106. The schematic illustrations show the illumination zones 120 of the cameras as patterned circles superimposed on the outline of the substrate 106. In alternative embodiments, the illumination zones 120 may be any shape or size relative to the substrate. As shown in FIG. 1D, the two cameras 112 are at a fixed pitch but each camera 112 is able to address up to their respective edge of the substrate 106. FIG. 1E shows the range of motion of one embodiment of the two camera design in which there is little or no overlap between the cameras at the center of the substrate, but the cameras are able to address the entire substrate. In an alternative embodiment, not shown, the pitch of the camera relative to the width of the substrate (i.e., dimension of the substrate along the Y axis) may be smaller than half the width thus increasing the amount of overlap of illumination zones 120 of the two cameras.

In operation, the lithographic tool 100 of FIGS. 1A-1E moves the substrate to an initial position beneath the cameras 112. The cameras then image, i.e. expose, the portions of the substrate in their respective illumination zones 120. After the initial imaging, either a) the cameras are moved along the Y axis to a next camera position or b) the chuck 104 and substrate 106 are moved along the X axis to a next substrate position or c) both. Then the substrate is again imaged by the cameras. This sequence of steps is then repeated until all the necessary imaging has been done and the substrate is removed for further processing (e.g., etching).

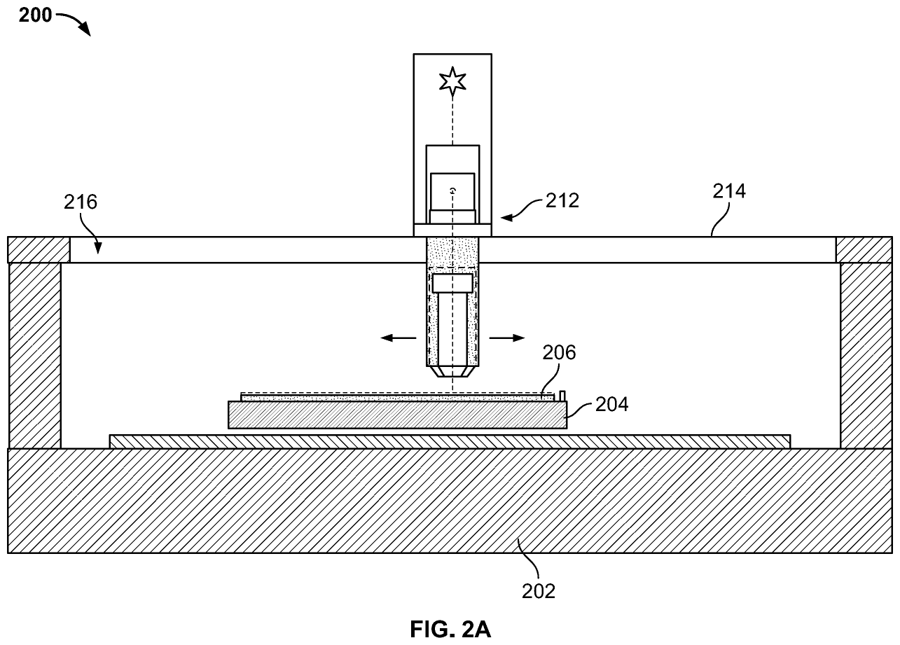

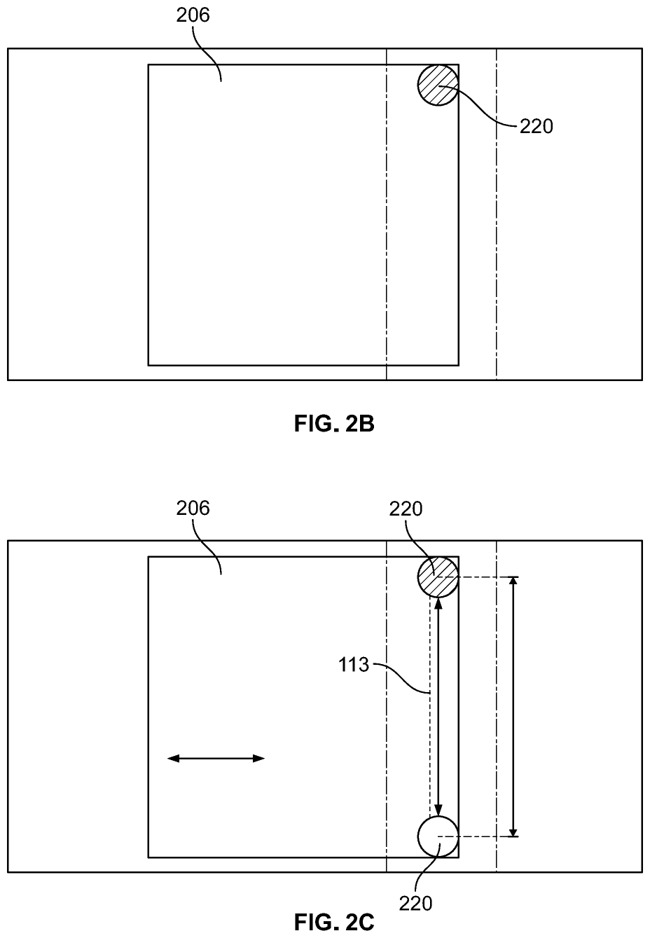

FIGS. 2A-C illustrate different views of a single camera embodiment of a separated axis lithographic tool. Corresponding to the views shown in FIGS. 1B, 1D and 1E, FIGS. 2A-C show how a single camera embodiment 200 can be designed to completely image a substrate 206 using only one camera 212. In this embodiment, the range of motion of the single camera in the Y axis, as illustrated in FIG. 2C, is sufficient for the illumination zone 220 of the camera to image the entire surface substrate 206. Camera 212 moves within a slot 216 in bridge 214 laterally with respect to the chuck 204 and the base 202 on which the chuck 204 moves.

As mentioned above, a projection camera 212 is but one type of process tool that may be used in conjunction with the separated axis lithography systems described herein. Other tools include: registration tools to identify and confirm the location of the substrate relative to the cameras or other components of the system; cleaning tools that maintain the surface of the substrate; and resist application tools, to name but a few. Any process tool now known or later developed may be used in conjunction with the systems described herein in addition to or instead of one or more cameras.

Similarly, embodiments may have one or two cameras, as described in detail above, or more. The systems describe above could be adapted to have any number of cameras including embodiment in which the three or more cameras are provided and are not co-linear. For example, a four-camera embodiment in which the cameras are provided in a square arrangement or an offset grid arrangement. Any number of cameras or process tools in any one-dimensional or two-dimensional arrangement may be used.

Yet another embodiment of the separated axis lithographic tool involves providing a high-precision subregion on the surface of the base (e.g., base 102 in FIGS. 1A-1E and base 202 in FIGS. 2A-C) beneath each projection camera. High-precision subregions are discrete surfaces polished or otherwise manipulated to obtain a very precise specification, e.g., flat to the extent that the variation in height of the surface in the subregion is less than 10,000, less than 1,000, less than 500, less than 100, less than 50 and, even, less than 10 Angstroms across the entire subregion. As the flatness of the chuck and substrate are affected by the flatness of the base, the addition of the high-precision subregions beneath the projection cameras can improve the performance of the tool. Stages provided with bases having such high-precision subregions are referred to as conformal stages. Conformal stages are discussed in greater detail in International Patent Application No. PCT/US2018/066991, filed Dec. 21, 2018, the disclosure of which is incorporated herein by reference in its entirety.

Notwithstanding that the numerical ranges and parameters setting forth the broad scope of the technology are approximations, the numerical values set forth in the specific examples are reported as precisely as possible. Any numerical value, however, inherently contain certain errors necessarily resulting from the standard deviation found in their respective testing measurements.

It will be clear that the systems and methods described herein are well adapted to attain the ends and advantages mentioned as well as those inherent therein. Those skilled in the art will recognize that the methods and systems within this specification may be implemented in many manners and as such are not to be limited by the foregoing exemplified embodiments and examples. In this regard, any number of the features of the different embodiments described herein may be combined into one single embodiment and alternate embodiments having fewer than or more than all of the features herein described are possible.

While various embodiments have been described for purposes of this disclosure, various changes and modifications may be made which are well within the scope contemplated by the present disclosure. For example, a lithographic tool with a more precise camera over a high-precision subregion may be paired with a second process tool over a normal subregion in situations in which such high precision is not necessary for the second process tool. Numerous other changes may be made which will readily suggest themselves to those skilled in the art and which are encompassed in the spirit of the disclosure.

1. A stepper for lithographic processing of semiconductor substrates comprising:
a chuck that moves only along an X axis of a coordinate system;
a bridge mounted over the chuck; and
at least one projection camera mounted on the bridge;
the at least one projection camera being movable along a Y axis of the coordinate system, a combined range of travel of the chuck along the X axis and the at least one projection camera along the Y axis being sufficient to address a field of view of the at least one projection camera to substantially an entire substrate mounted on the chuck.

2. The stepper for lithographic processing of substrates of claim 1, the at least one projection camera comprising a first projection camera and a second projection camera each addressable to about one half of the substrate on the chuck, respectively.

3. The stepper for lithographic processing of substrates of claim 2, wherein a field of view of the substrate addressable by the first projection camera and a field of view of the substrate addressable by the second projection camera do not overlap.

4. The stepper for lithographic processing of substrates of claim 2, wherein the first and second projection cameras have a fixed pitch.

5. The stepper for lithographic processing of substrates of claim 2, further comprising:
a pitch adjustment mechanism coupled between the first and second projection cameras, the pitch adjustment mechanism having a plurality of positions, each of the plurality of positions corresponding to a different pitch between the first and second projection cameras.

6. The stepper for lithographic processing of substrates of claim 2, wherein the at least one projection camera is controllably moveable along the Y axis over a cushion of air created by an air bearing.

7. The stepper for lithographic processing of substrates of claim 6, wherein the air bearing is moveable independent of the at least one projection camera.

8. A stepper for lithographic processing of semiconductor substrates comprising:
a chuck that moves only along an X axis of a coordinate system;
a bridge mounted over the chuck; and
a first projection camera and a second projection camera, each mounted on the bridge and movable along a Y axis of the coordinate system,
a combined range of travel of the chuck along the X axis and the first and second projection cameras along the Y axis being sufficient to address a field of view of the first and second projection cameras to substantially an entire substrate mounted on the chuck.

9. The stepper for lithographic processing of substrates of claim 8, wherein the first and second projection cameras are each addressable to about one half of the substrate on the chuck.

10. The stepper for lithographic processing of substrates of claim 8, wherein a field of view of the substrate addressable by the first projection camera and a field of view of the substrate addressable by the second projection camera do not overlap.

11. The stepper for lithographic processing of substrates of claim 8, wherein the first and second projection cameras have a fixed pitch.

12. The stepper for lithographic processing of substrates of claim 8, further comprising:
a pitch adjustment mechanism coupled between the first and second projection cameras, the pitch adjustment mechanism having a plurality of positions, each of the plurality of positions corresponding to a different pitch between the first and second projection cameras.

13. The stepper for lithographic processing of substrates of claim 8, wherein the first and second projection cameras are controllably moveable along the Y axis over a cushion of air created by an air bearing.

14. The stepper for lithographic processing of substrates of claim 4, wherein an air bearing is moveable independent of first and second projection cameras.

15. A stepper for lithographic processing of semiconductor substrates comprising:
a chuck that moves only along an X axis of a coordinate system;
a bridge mounted over the chuck; and
a projection camera mounted on the bridge and movable along a Y axis of the coordinate system,
a combined range of travel of the chuck along the X axis and the projection camera along the Y axis being sufficient to address a field of view of the projection camera to substantially an entire substrate mounted on the chuck.

16. The stepper for lithographic processing of substrates of claim 15, wherein the projection camera is controllably moveable along the Y axis over a cushion of air created by an air bearing.

17. The stepper for lithographic processing of substrates of claim 16, wherein the air bearing is moveable independent of the projection camera.

18. The stepper for lithographic processing of substrates of claim 1, further comprising a sawyer motor is configured to move the at least one projection camera in the y axis.

19. The stepper for lithographic processing of substrates of claim 8, further comprising a sawyer motor is configured to move the first projection camera in the y axis.

20. The stepper for lithographic processing of substrates of claim 15, further comprising a sawyer motor is configured to move first projection camera in the y axis.
